(19) United States
(12) Patent Application Publication
(10) Pub. No.: US 2015/0185911 A1
(43) Pub. Date: Jul. 2, 2015

(54) FLEXIBLE TOUCH PANEL AND MANUFACTURING METHOD THEREOF

(71) Applicant: Samsung Display Co., Ltd., Yongin-City (KR)

(72) Inventor: Dae Won KIM, Hwaseong-si (KR)

(21) Appl. No.: 14/464,559

(22) Filed: Aug. 20, 2014

(30) Foreign Application Priority Data
Dec. 27, 2013 (KR) 10-2013-0166027

(51) Int. Cl. G06F 3/044; H03K 17/96

(52) U.S. Cl. CPC G06F 3/044; H03K 17/9622; H03K 2017/9613; H03K 2217/960755; H03K 2217/960745; G06F 2203/04102

(57) ABSTRACT

A touch panel and manufacturing method thereof are disclosed. In one aspect, the touch panel includes a flexible substrate and a plurality of touch sensors formed over the flexible substrate. Each of the touch sensors includes a first conductive pattern, a second conductive pattern at least partially overlapping the first conductive pattern, and an insulating layer interposed between and electrically insulating the first and second conductive patterns. The insulating layer is formed at least in part of an elastic material and the distance between the first and second conductive patterns is configured to vary as the flexible substrate is bent.

### INCORPORATION BY REFERENCE TO ANY PRIORITY APPLICATIONS

This application claims priority to and the benefit of Korean Patent Application No. 10-2013-0166027 filed in the Korean Intellectual Property Office on Dec. 27, 2013, the entire contents of which are incorporated herein by reference.

### BACKGROUND

1. Field

The described technology generally relates to a touch panel and a manufacturing method thereof.

2. Description of the Related Technology

Flat panel displays (FPDs) such as liquid crystal displays (LCDs), organic light-emitting diode (OLED) displays, and electrophoretic displays (EPDs) include a field generating electrode and an electro-optical active layer. LCDs include a liquid crystal layer as the electro-optical active layer, OLED displays include an organic emission layer, and EPDs include charged particles. The field generating electrode is connected to a switching element such as a thin film transistor (TFT) to receive a data signal and the electro-optical active layer converts the data signal into optical signals to display an image.

Some flat panel displays also include a touch sensor as an input device. The touch sensor is used to determine whether an object contacts the screen and to generate contact information about a contact position by detecting a change in pressure, charge, or light which is applied to the screen, when a user contacts the screen with a finger, touch pen, or the like. The display device receives an image signal based on the contact information.

The above information disclosed in this Background section is only intended to facilitate the understanding of the background of the described technology and therefore it may contain information that does not constitute the prior art that is already known in this country to a person of ordinary skill in the art.

### SUMMARY OF CERTAIN INVENTIVE ASPECTS

One inventive aspect is a touch panel for a flexible display device which is capable of detecting a bending position and a bending degree.

Another aspect is a touch panel including a flexible substrate and a plurality of contact sensing units positioned on the flexible substrate. The contact sensing unit includes a first conductive pattern unit, a second conductive pattern unit partially overlapping the first conductive pattern unit, and an insulating layer positioned between the first and second conductive pattern units. The insulating layer is formed of a compressible elastic material and a distance between the first and second conductive pattern units is varied as the substrate bends.

The first conductive pattern unit may include a first sub-region and a second sub-region having a greater thickness than the first sub-region.

The contact sensing unit may have a flexible property and a capacitance between the first and second conductive pattern units may increase as a distance therebetween decreases.

The first conductive pattern unit may be in the shape of protrusions and depressions including one second sub-region positioned at a central part and two first sub-regions respectively positioned at lateral sides of the second sub-region.

A passivation layer may be further included to cover the contact sensing unit.

The first and second conductive pattern units may have cross-sectional shapes that are symmetrical to each other.

The first and second conductive pattern units may have cross-sectional shapes that complementarily fit into each other.

The first and second conductive pattern units may be made of silver nanowire.

The flexible substrate may be made of a polymer resin layer.

Another aspect is a method of manufacturing a touch panel including laminating a flexible conductor on a substrate, forming a plurality of first conductive pattern units by patterning the flexible conductor, laminating an insulating layer on the plurality of first conductive pattern units, and forming a plurality of second conductive pattern units having cross-sectional shapes that complementarily fit into the first conductive pattern units. The insulating layer is made of a compressible elastic material and a distance between the first and second conductive pattern units is varied as the substrate bends.

Forming the first conductive pattern unit may include forming a first sub-region and forming a second sub-region having a greater thickness than the first sub-region.

The contact sensing unit may have a flexible property and a capacitance between the first and second conductive pattern units may increase as a distance therebetween decreases.

The first conductive pattern unit may be formed to have a cross-section which is in the shape of protrusions and depressions including the one second sub-region and the two first sub-regions respectively positioned at lateral sides of the second sub-region.

A passivation layer covering the contact sensing unit may be further included.

The first and second conductive pattern units may be formed to have cross-sectional shapes that are symmetrical to each other.

The first and second conductive pattern units may be formed to have cross-sectional shapes that complementarily fit into each other.

The first and second conductive pattern units may be made of silver nanowire.

The flexible substrate may be made of a high polymer resin layer.

Another aspect is a touch panel including a flexible substrate and a plurality of touch sensors formed over the flexible substrate, wherein each of the touch sensors includes a first conductive pattern, a second conductive pattern at least partially overlapping the first conductive pattern, and an insulating layer interposed between and electrically insulating the first and second conductive patterns, wherein the insulating layer is formed at least in part of an elastic material and wherein the distance between the first and second conductive patterns is configured to vary as the flexible substrate is bent.

The first conductive pattern includes a first sub-region and a second sub-region having a greater thickness than the first sub-region. Each of the touch sensors is flexible and the first and second conductive patterns of each touch sensor have a capacitance therebetween that increases as the distance therebetween decreases. A cross-section of each of the first conductive patterns has a step shape and the first sub-region is formed on opposing sides of the second sub-region in each of the first conductive patterns. The touch panel further includes a passivation layer at least partially covering the touch sensors. Each of the first and second conductive patterns has a cross-sectional shape that is substantially symmetrical. The first and second conductive patterns have cross-sectional shapes that are complementary. The first and second conductive patterns are formed at least in part of silver nanowire. The flexible substrate is formed at least in part of a polymer resin layer.

Another aspect is a method of manufacturing a touch panel including forming a flexible conductor over a substrate, patterning the flexible conductor so as to form a plurality of first conductive patterns, forming an insulating layer over the first conductive patterns, and forming a plurality of second conductive patterns over the insulating layer, wherein the insulating layer electrically insulates the first conductive patterns from the second conductive patterns, wherein the first and second conductive patterns have cross-sectional shapes that are complementary, wherein the insulating layer is formed at least in part of an elastic material, and wherein the distance between the first and second conductive patterns is configured to vary as the substrate is bent.

The forming of each of the first conductive patterns includes forming a first sub-region and forming a second sub-region having a greater thickness than the first sub-region. The touch sensor is flexible and the first and second conductive patterns have a capacitance therebetween that increases as the distance therebetween decreases. A cross-section of each of the first conductive patterns has a step shape and the first sub-region is formed on opposing sides of the second sub-region in each of the first conductive patterns. The method further includes forming a passivation layer at least partially covering the touch sensors. The first and second conductive patterns have cross-sectional shapes that are substantially symmetrical. The first and second conductive patterns are formed at least in part of silver nanowire. The substrate includes a polymer resin layer.

Another aspect is a flexible display device including a flexible display panel including a plurality of pixels and a touch panel formed over the display panel, wherein the touch panel includes a flexible substrate, a plurality of first conductive patterns formed over the flexible substrate, a plurality of second conductive patterns at least partially overlapping the first conductive patterns, and an insulating layer interposed between and electrically insulating the first and second conductive patterns, wherein the insulating layer is formed at least in part of an elastic material.

Each of the first conductive patterns includes a first sub-region and a second sub-region having a thickness that is greater than that of the first sub-region. The flexible display device further includes a controller configured to measure a change in capacitance between the first and second conductive patterns and determine that the change in capacitance is due to bending of the touch panel when the change in capacitance is within a predetermined range.

According to at least one embodiment, the touch panel can display an appropriate image based on the detected position of a bend in the panel and the bending degree.

### BRIEF DESCRIPTION OF THE DRAWINGS

FIG. 1 is a perspective view of a curved display device according to an exemplary embodiment.

FIG. 2 is a top plan view of a touch panel according to an exemplary embodiment.

FIG. 3 is a cross-sectional view of FIG. 2 taken along the line III-III.

FIG. 4 is a flowchart showing a driving mechanism of the touch panel according to an exemplary embodiment.

FIG. 5 and FIG. 6 are cross-sectional views of the touch panel according to another exemplary embodiment.

FIG. 7 is a graph showing capacitance according to distance.

### DETAILED DESCRIPTION OF CERTAIN INVENTIVE EMBODIMENTS

The described technology will be presented more fully hereinafter with reference to the accompanying drawings, in which exemplary embodiments are shown. As those skilled in the art would realize, the described embodiments may be modified in various different ways, all without departing from the spirit or scope of the described technology.

In the drawings, the thickness of layers, films, panels, regions, etc. may be exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terms “first”, “second”, etc. may be used to describe various constituent elements, but the constituent elements should not be limited to the terms. The terms should be used only for differentiating one constituent element from another constituent element.

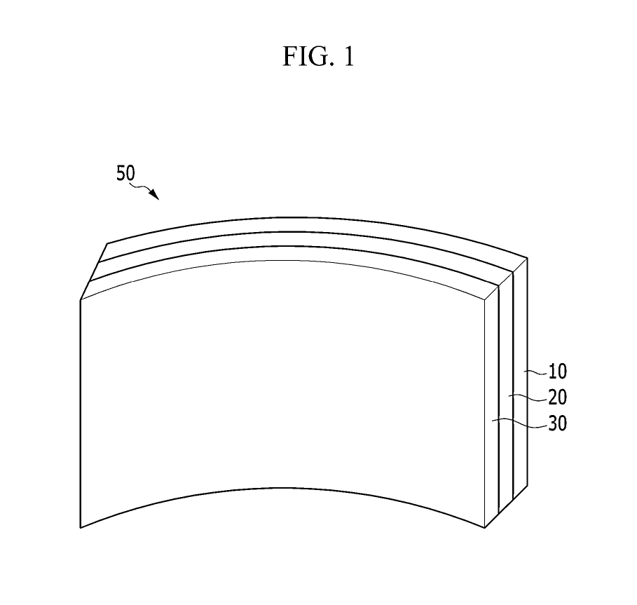

A touch panel 20 according to an exemplary embodiment will now be described with reference to FIGS. 1 to 3.

Referring to FIG. 1, the curved display device includes a display panel 10, a touch panel 20, and a window or protective layer 30. The display panel 10 displays an image, the touch panel 20 senses a contact, and the window 30 protects the display panel 10 and the touch panel 20.

A display device 50 according to an exemplary embodiment is a curved display device. The display device can be formed into a curved shape by being concavely or convexly bent.

According to the embodiment illustrated in FIG. 1, the display device 50 has a landscape orientation with a shorter vertical height than horizontal length and is curved in a horizontal direction. However, the described technology is not limited thereto. In other embodiments, the display device 50 has a portrait orientation having a longer vertical height than horizontal length and is curved in a vertical direction, but the described technology is not limited thereto. In still other embodiments, the display device 50 is a flat panel display device.

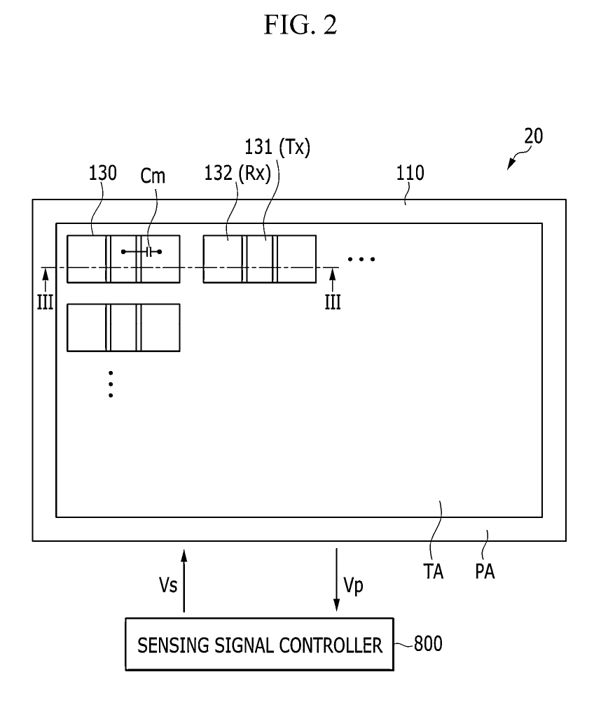

Referring to FIG. 2, the touch panel 20 according to the exemplary embodiment includes a contact sensing unit or touch sensor 130 and a sensing signal controller 800 for controlling contact sensing.

As used herein, contact refers not only to when an external object directly contacts the window 50, but also when the external object approaches the window 50.

The touch panel 20 includes a plurality of sensing input electrodes Tx (also referred to as first conductive pattern units or first conductive patterns) and a plurality of sensing output electrodes Rx (also referred to as second conductive pattern units or second conductive patterns) that are arranged in a matrix. The sensing input electrodes Tx and sensing output electrodes Rx are spaced apart from each other at a predetermined interval.

According to at least one embodiment, one sensing input electrode 131 and one sensing output electrode 132 are coupled to form one contact sensing unit 130.

At least some of the sensing input electrodes Tx can be connected to each other or separated from each other in the touch panel 20. Similarly, at least some of the sensing output electrodes Rx can be connected to each other or separated from each other in the touch panel 20.

In some embodiments, the sensing input electrodes Tx arranged in the same column are electrically connected to each other and the sensing output electrodes Rx arranged in the same column are electrically connected to each other.

In some embodiments, the sensing output electrodes Rx arranged in one column are separated from each other when the sensing input electrodes Tx arranged in one column are connected to each other. In other embodiments, the sensing input electrodes Tx arranged in one column are separated from each other when the sensing output electrodes Rx arranged in one column are connected to each other.

The sensing input and output electrodes Tx and Rx can be formed of a transparent conductive material having a flexible property such as silver nanowire (AgNW), a metal mesh, carbon nanotubes, or grapheme, but they are not limited thereto.

The sensing input and output electrodes Tx and Rx may have one side length of about several millimeters, but the sizes of the sensing input and output electrodes Tx and Rx can be adjusted according to a selected input object or contacting method.

Referring to FIG. 2, the sensing input and output electrodes Tx and Rx are formed in a touch area TA on a substrate 110. A plurality of contact sensing units are positioned in the touch area TA and wires extending from the contact sensing units are located in a peripheral area PA.

When the touch panel 20 is attached to the display device as an additional panel, the substrate 110 of the touch panel 20 is separately provided in addition to the substrate of the display device. Alternatively, when the sensing input and output electrodes Tx and Rx are formed on an outer surface of the substrate of the display device (on-cell type) or an inner surface thereof (in-cell type), the substrate of the display device also functions as the substrate 110 of the touch panel 20.

As shown in FIG. 2, the sensing input electrode 131 and the sensing output electrode 132 neighboring each other form a sensing capacitor Cm. The sensing capacitor Cm functions as a contact sensor and may be a mutual sensing capacitor. The sensing capacitor Cm receives a sensing input signal Vs through the sensing input electrode 131 and outputs a change in the stored charge as a sensing output signal Vp.

The sensing signal controller 800 is connected to the sensing input and output electrodes 131 and 132 of the touch panel 20. The sensing signal controller 800 transmits the sensing input signal Vs to the sensing input electrode 131 and receives the sensing output signal Vp from the sensing output electrode 132. The sensing signal controller 800 processes the sensing output signal Vp to produce contact information about whether contact has occurred and the contacting position.

The operation of the contact sensing device will now be described with reference to FIGS. 1 and 2.

When the sensing input electrode 131 receives the sensing input signal Vs from the sensing signal controller 800, the sensing capacitor Cm is charged to a predetermined charge amount. The sensing input signal Vs is sequentially inputted to a column of sensing input electrodes 131 or is simultaneously inputted thereto.

When an external object contacts the window 30, the amount of charge stored in the sensing capacitor Cm is altered such that the sensing output signal Vp is outputted from the sensing output electrode 132.

According to some embodiments, when the window 30 is contacted by the external object the sensing output signal Vp has a lower voltage level than when there is no contact.

The sensing signal controller 800 receives the sensing output signal Vp, performs sampling and A/D conversion on the sensing output signal Vp, and generates a digital sensing signal. The sensing signal controller 800, or an additional decision making circuit for performing an operational process, generates contact information such as the contact state (i.e. whether contact has occurred) and the contact position.

Similarly, when the sensing input electrode 131 receives the sensing input signal Vs from the sensing signal controller 800, the sensing capacitor Cm is charged to the predetermined amount of charge. The sensing input signal Vs may be sequentially inputted to the column of the sensing input electrodes 131 or simultaneously inputted thereto.

When an external force is applied to the touch panel 20, the distance between the sensing input electrode 131 and the sensing output electrode 132 is altered, causing a change in the stored charge amount of the sensing capacitor Cm, thereby outputting the sensing output signal Vp from the sensing output electrode 132. Accordingly, the touch panel 20 senses bending via a change in the charge amount due to such variations in distance when the touch panel 20 is bent.

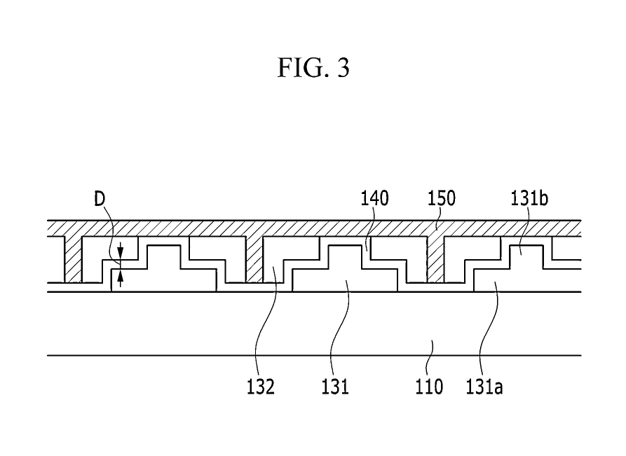

The components of the touch panel will be described in detail with reference to FIG. 2 and FIG. 3.

The substrate 110 is positioned at a lower part of the touch panel 20. The touch panel 20 has a laminated structure and is illustrated to have a planar shape, but it is not limited thereto, and in other embodiments, the touch panel has a curved shape. The substrate 110 may be formed of various materials such as glass and plastic, or may be formed by using a laminated structure of organic and inorganic layers. As an example, the substrate 110 may be formed of a polymer resin layer.

A first conductive pattern unit 131 is formed on the substrate 110 and includes a first sub-region 131a and a second sub-region 131b having a greater thickness than the first sub-region 131a. In the embodiment of FIG. 3, the first conductive pattern unit 131 includes one second sub-region 131b and two first sub-regions 131a respectively positioned on opposing sides of the second sub-region 131b. The cross-section of the first conductive pattern unit 131 has a step shape including protrusions and depressions.

The first conductive pattern unit 131 may be formed of a transparent flexible material, which may be one of silver nanowire (AgNW), a metal mesh, carbon nanotubes, and grapheme.

An insulating layer 140 is formed on the first conductive pattern unit 131 and the substrate 110, and covers the first conductive pattern unit 131. The insulating layer 140 electrically insulates the first conductive pattern units 131 from second conductive pattern units 132 and may be formed of any electrically insulating material, for example, an elastic insulating material.

When the first and second conductive pattern units 131 and 132 are elongated as the touch panel bends, the thickness of the insulating layer 140 decreases or increases due to its elasticity. In other words, the insulating layer 140 can be compressed as the distance between the first and second conductive pattern units 131 and 132 decreases due to bending, while the insulating layer 140 may recover its original thickness as the distance therebetween increases.

The second conductive pattern unit 132 forms the sensing capacitor Cm together with the first conductive pattern unit 131 and the first and second conductive pattern units 131 and 132, as shown in FIG. 2, form one contact sensing unit 130. However, the described technology is not limited thereto, and a plurality of first conductive pattern units 131 and a plurality of second conductive pattern units 132 may form one contact sensing unit 130.

The second conductive pattern unit 132 may have any shape such that its distance from the first conductive pattern unit 131 can be varied as the touch panel bends and the second conductive pattern unit 132 partially overlaps the first conductive pattern unit 131.

The shape of the second conductive pattern unit 132 will now be described in more detail.

According to some embodiments, the first and second conductive pattern units 131 and 132 have cross-sectional shapes that are mutually complementary to each other. In detail, when the first conductive pattern unit 131 has a cross-sectional shape having protrusions and depressions as shown in FIG. 3, the second conductive pattern unit 132 is formed such that the cross-sections of the first and second conductive pattern units 131 and 132 are fitted into each other to form a rectangle.

According to the structure described above, the second conductive pattern unit 132 has a cross-sectional shape which includes a substantially inverted L-shaped cross-sectional shape overlapping the first sub-region positioned at the left side of the first conductive pattern unit 131 and a cross-sectional shape that is symmetric thereto with respect to the Y-axis and overlaps the first sub-region positioned at the right side of the first conductive pattern unit 131.

However, in the FIG. 3 embodiment, the second conductive pattern unit 132 does not cover the top surface of the second sub-region 131b included in the first conductive pattern unit 131.

As described above, the shapes of the first and second conductive pattern units 131 and 132 are complementary to each other to form a rectangular cross-section such that their cross-sectional shapes can fit into each other.

The second conductive pattern unit 132 may be formed of a transparent flexible material, which may be one of silver nanowire (AgNW), a metal mesh, carbon nanotubes, and graphene.

A passivation layer 150 is formed on a top surface of the second sub-region 131b in the first and second conductive pattern units 131 and 132 and covers the overall substrate 110 including the second conductive pattern unit 132 and the insulating layer 140.

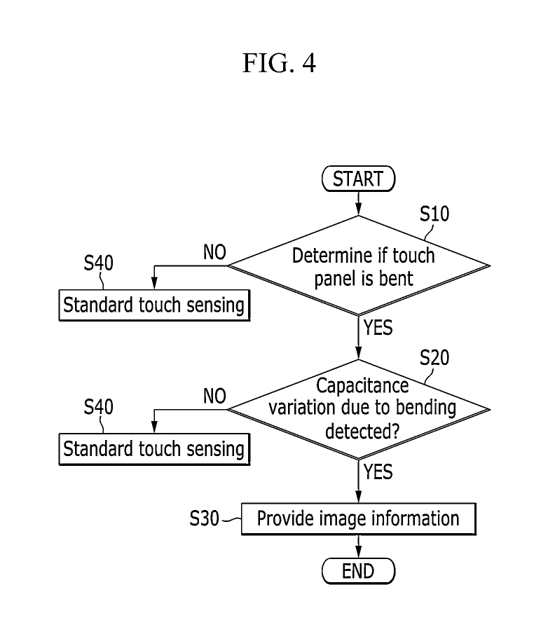

FIG. 4 is a flowchart showing a driving mechanism of the touch panel according to an exemplary embodiment. In some embodiments, the method of FIG. 4 is implemented in a conventional programming language, such as C or C++ or another suitable programming language. The program can be stored on a computer accessible storage medium of the display device 50. In certain embodiments, the storage medium includes a random access memory (RAM), hard disks, floppy disks, digital video devices, compact discs, video discs, and/or other optical storage mediums, etc. The program may be stored in a processor. The processor can have a configuration based on, for example, i) an advanced RISC machine (ARM) microcontroller and ii) Intel Corporation's microprocessors (e.g., the Pentium family microprocessors). In certain embodiments, the processor is implemented with a variety of computer platforms using a single chip or multichip microprocessors, digital signal processors, embedded microprocessors, microcontrollers, etc. In another embodiment, the processor can execute applications with the assistance of operating systems such as Unix, Linux, Microsoft DOS, Microsoft Windows 7/Vista/2000/9x/ME/XP, Macintosh OS, OS/2, Android, iOS and the like. In another embodiment, at least part of the procedure can be implemented with embedded software. Depending on the embodiment, additional states may be added, others removed, or the order of the states changed in FIG. 4.

First, a controller (not shown) is driven to determine if the touch panel is bent (S10). When the controller is not driven and the sensing signal controller detects a capacitance variation, the capacitance variation is recognized as standard touch input and the touch panel detects the input in a standard touch sensing mode.

Next, when the controller is driven and does not detect a variation in capacitance, it recognizes that no bending and no touch input has occurred in the display device. Thus, the touch panel detects touch input in a standard touch sensing mode.

However, when the controller is driven and then detects a variation in capacitance, the controller determines whether the variation in capacitance is due to the bending in the touch panel or the display device including the touch panel (S20). When the controller determines that the variation is due to the bending, it provides appropriate image information to the corresponding region of the display panel. Otherwise, the touch panel detects touch input in a standard touch sensing mode.

When external forces are applied to the touch panel, the distance between the sensing input electrode 131 and the sensing output electrode 132 is altered to change the stored charge amount in the sensing capacitor Cm and the degree of bending and the bending position can be detected by the sensing output signal Vp generated due to the change in store charge.

Accordingly, the distance between the sensing input electrode 131 and sensing output electrode 132 is varied according to a distance D between a top surface of the first sub-region of the sensing input electrode 131 and a bottom surface of the sensing output electrode 132 facing thereto on a plane and this change in the stored charge amount is detected.

In detail, the charge amount stored in the sensing capacitor Cm increases as the distance between the sensing input electrode 131 and sensing output electrode 132 decreases and the charge amount stored in the sensing capacitor Cm decreases as the distance between the sensing input electrode 131 and sensing output electrode 132 increases. Thus, the bending in the display device is detected by sensing the change in the stored charge amount.

The capacitance variation due to touch input is different from the capacitance variation due to the bending of a panel. Accordingly, when the variation in capacitance is detected, the type of input such as direct touch, hovering, or bending can be differentiated depending on the ranges in which the measured capacitance variations belong.

As an example, the degree of variation in capacitance due to touch input may be greater than that due to hovering or bending.

Accordingly, when the variation in capacitance is in the range typical of direct touch input, the variation can be recognized as touch input. Further, when the variation in capacitance is in the range of bending, the variation can be recognized as bending of the touch panel.

A method of manufacturing a touch panel according to an exemplary embodiment will now be described with reference to FIGS. 1 to 4 described above.

First, a substrate 110 is provided and a flexible conductor is laminated on the substrate 110. The conductor may be formed of a transparent flexible material, which may be one of silver nanowire (AgNW), a metal mesh, carbon nanotubes, and graphene.

Next, a first conductive pattern unit 131 including a first sub-region 131a and a second sub-region 131b is formed by patterning the flexible conductor. The first conductive pattern unit 131 is positioned on the substrate 110 and is formed to include a first sub-region 131a and a second sub-region 131b having a greater thickness than the first sub-region 131a.

According to some embodiments, the first conductive pattern unit 131 has a cross-section with a substantially step shape including protrusions and depressions. The first conductive pattern unit 131 includes one second sub-region 131b and two first sub-regions respectively positioned 131a on opposing sides of the second sub-region 131b.

Next, an insulating material is spread on the first conductive pattern unit 131 and the substrate 110 so as to form an insulating layer 140.

The insulating layer 140 electrically insulates the first conductive pattern units 131 from the second conductive pattern unit 132 and may be formed of any electrically insulating material, for example, an elastic insulating material.

When the first and second conductive pattern units 131 and 132 are elongated as the touch panel bends, the width of the insulating layer 140 can be decreased or increased due to its elasticity.

Next, the flexible conductor is laminated again on the insulating layer 140. The second conductive pattern unit 132 having a cross-section that can be fitted into the first conductive pattern unit 131 is formed by patterning the flexible conductor. The flexible conductor may be formed of the same material as the first conductive pattern unit 131.

The second conductive pattern unit 132 may have any shape such that its distance from the first conductive pattern unit can be varied as the touch panel bends. As an example, the second conductive pattern unit 132 may have a complementary cross-sectional shape.

When the first conductive pattern unit 131 has a cross-sectional shape having protrusions and depressions as shown in FIG. 3, the second conductive pattern unit 132 is formed such that the cross-sections of the first and second conductive pattern units 131 and 132 are fitted into each other to form a substantially rectangular shape.

According to the structure described above, the second conductive pattern unit 132 has a cross-sectional shape which includes a substantially inverted L-shaped cross-sectional shape overlapping the first sub-region 131a positioned at the left side of the first conductive pattern unit 131 and a cross-sectional shape that is symmetric thereto with respect to the Y-axis and overlaps the first sub-region 131a positioned at the right side of the first conductive pattern unit 131.

As described above, the shapes of the first and second conductive pattern units 131 and 132 that are complementary may form a rectangular cross-section, in other words, the cross-section of the two pattern units fit into each other.

Next, a passivation layer 150 is formed on the second conductive pattern unit 132 and the insulating layer 140.

The touch panel formed by the aforementioned method outputs a sensing output signal Vp to the sensing output electrode 132 according to an applied external force as the distance between the sensing input electrode 131 and the sensing output electrode 132 is varied to cause a change in the charge amount stored in the sensing capacitor Cm.

The touch panel 20 senses bending based on the change in the stored charge amount due to such a variation in distance.

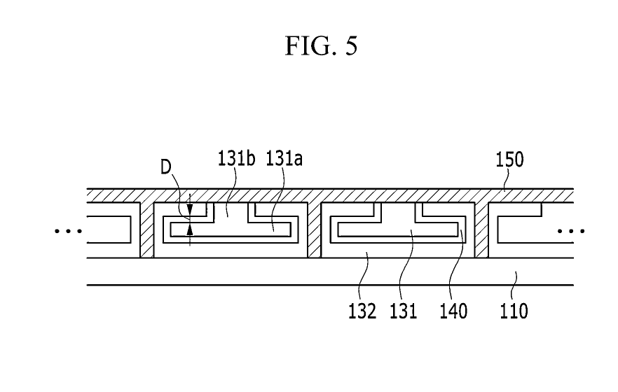

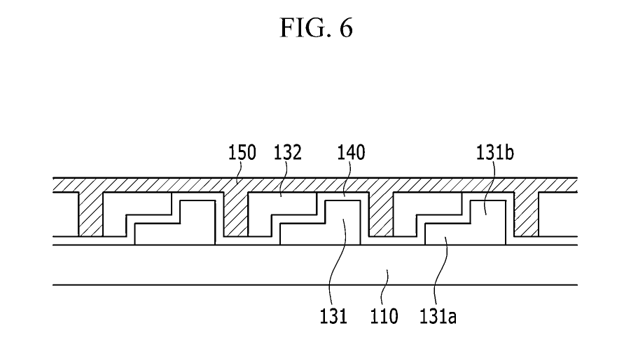

A touch panel according to another exemplary embodiment will now be described with reference to FIGS. 5 and 6.

Referring to FIG. 5, a first conductive pattern unit 131 and an insulating layer 140 are formed over a substrate 110.

In this embodiment, the substrate 110 is positioned at a lower part of the touch panel having a laminated structure and is illustrated to have a planar shape, but it is not limited thereto, and may have a curved shape.

The substrate 110 may be formed of various materials such as glass or plastic, or may be formed by using a laminated structure of organic and inorganic layers. As an example, the substrate 110 may be formed of a polymer resin layer.

The first conductive pattern unit 131 is formed over the substrate 110 and includes a first sub-region 131a and a second sub-region 131b having a greater thickness than the first sub-region 131a. The first conductive pattern unit 131 has a substantially step shape including protrusions and depressions. The first conductive pattern unit 131 includes one second sub-region 131b in a central position and two first sub-regions 131a respectively positioned at opposing sides of the second sub-region 131b. That is, the first conductive pattern unit 131 has substantially the same cross-sectional shape as the embodiment described in connection with FIG. 3.

The first conductive pattern unit 131 may be formed of a transparent flexible material, which may be one of silver nanowire (AgNW), a metal mesh, carbon nanotubes, and graphene.

The insulating layer 140 is formed to enclose the first conductive pattern unit 131 such that it substantially completely encloses the first conductive pattern 131 except for a top surface of the second sub-region 131b. The insulating layer 140 electrically insulates the first conductive pattern units 131 from the second conductive pattern units 132 and may be formed of any electrically insulating material, for example, an elastic insulating material.

The insulating layer 140 can also be elongated to decrease the thickness thereof when the first and second conductive pattern units 131 and 132 are elongated as the touch panel bends.

The second conductive pattern unit 132 has a shape enclosing the first conductive pattern unit 131 so as to form a capacitor together with the first conductive pattern unit 131. In other words, the second conductive pattern unit 132 has a cross-sectional shape that is mutually complementary to that of the first conductive pattern unit 131.

In detail, when the first conductive pattern unit 131 has a cross-sectional shape having protrusions and depressions as shown in FIG. 5, the second conductive pattern unit 132 is formed such that the cross-sections of the first and second conductive pattern units 131 and 132 are fitted into each other to form a rectangle.

According to FIG. 5, the second conductive pattern unit 132 includes a substantially inverted L-shaped cross-section and a cross-sectional shape symmetric thereto with respect to the Y-axis so as to cover a surface of the first sub-region 131a of the first conductive pattern unit 131. However, the second conductive pattern unit 132 does not cover a top surface of the second sub-region 131b of the first conductive pattern unit 131. That is, the shapes of the first and second conductive pattern units 131 and 132 that are complementary to each other form a rectangular cross-section.

Further, according to another exemplary embodiment, in contrast to the embodiment shown in FIG. 3, a second conductive pattern unit 132 has a shape that substantially completely encloses a bottom surface of a first conductive pattern unit 131.

According to the structure described above, a portion of the second conductive pattern unit 132 is formed on the substrate 110 and an insulating layer 140 and a bottom surface of the first conductive pattern unit 131 are formed on the second conductive pattern unit 132.

The second conductive pattern unit 132 may be formed of a transparent flexible material, which may be one of silver nanowire (AgNW), a metal mesh, carbon nanotubes, and graphene.

The first and second conductive pattern units 131 and 132 can be manufactured using a plurality of masks and the first and second conductive pattern units 131 and 132 formed on the same layer can be manufactured by using the same mask and the same material. A passivation layer 150 is formed on a top surface of the second sub-region 131b of the first and second conductive pattern units 131 and 132 and covers the overall substrate 110 including the second conductive pattern unit 132 and the insulating layer 140.

Referring now to the embodiment of FIG. 6, the first conductive pattern unit 131 and the insulating layer 140 are formed on the substrate 110.

The substrate 110 is positioned at a lower end of a touch panel having a laminated structure and is illustrated to have a planar shape, but it is not limited thereto, and may have a curved shape. The substrate 110 may be formed of various materials such as glass or plastic or may be formed by using a laminated structure of organic and inorganic layers. As an example, the substrate 110 may be formed of a polymer resin layer.

The first conductive pattern unit 131 is formed on the substrate 110 and includes the first sub-region 131a and the second sub-region 131b having a greater thickness than the first sub-region 131a. The first conductive pattern unit 131 includes one second sub-region 131b and one first sub-region 131a and has a substantially reverse L-shaped cross-section.

The first conductive pattern unit 131 may be formed of a transparent flexible material which may be one of silver nanowire (AgNW), a metal mesh, carbon nanotubes, and graphene.

The insulating layer 140 is formed to enclose the first conductive pattern unit 131 such that it substantially completely encloses the second sub-region 131b of the first conductive pattern unit 131. The insulating layer 140 electrically insulates the first conductive pattern units 131 from the second conductive pattern unit 132 and may be formed of any electrically insulating material, for example, an elastic insulating material.

The insulating layer 140 can also be elongated to decrease the thickness thereof when the first and second conductive pattern units 131 and 132 are elongated as the touch panel bends.

The second conductive pattern unit 132 forms a capacitor together with the first conductive pattern unit 131 and has a shape that is symmetrical to that of the first conductive pattern unit 131.

Referring to FIG. 6, the second conductive pattern unit 132 has a cross-sectional shape that is mutually complementary to that of the first conductive pattern unit 131. In detail, when the first conductive pattern unit 131 has a substantially reverse L-shaped cross-sectional shape, as shown in FIG. 6, the second conductive pattern unit 132 has a substantially inverse L-shaped cross-sectional shape such that the cross-sections of the first and second conductive pattern units 131 and 132 are fitted into each other to form a substantially rectangular shape.

Accordingly, the cross-sections of the first and second conductive pattern units 131 and 132 may complementarily form the rectangle with respect to each other.

The second conductive pattern unit 132 may be formed of a transparent flexible material, which may be one of silver nanowire (AgNW), a metal mesh, carbon nanotubes, and graphene.

A passivation layer 150 is formed on a top surface of the second sub-region 131b in the first and second conductive pattern units 131 and 132 and covers the overall substrate 110 including the second conductive pattern unit 132 and the insulating layer 140.

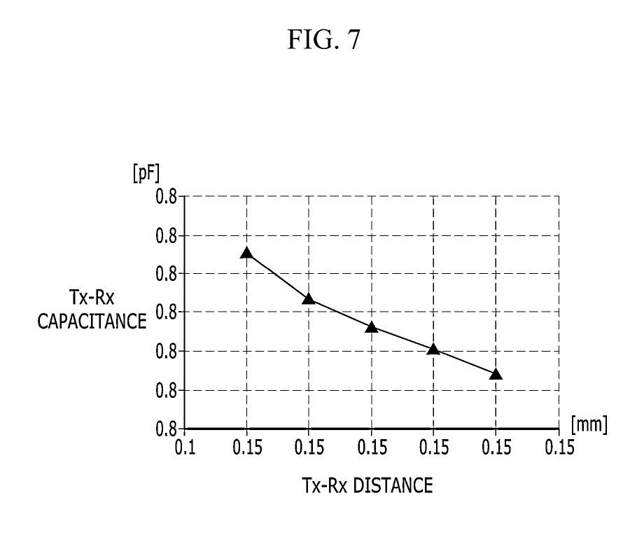

The basic mechanism of a touch panel will now be described with reference to FIG. 7. FIG. 7 is a graph of capacitance according to distance.

As shown in FIG. 7, the capacitance between the sensing input electrode Tx and the sensing output electrode Rx decreases as a distance between the sensing input electrode Tx and the sensing output electrode Rx increases. Thus, when the distance between the sensing input and output electrodes Tx and Rx decreases due to bending of the touch panel, the capacitance therebetween increases and the position and degree of the bending in the display device can be detected by such a variation in capacitance.

Since the distance between the sensing input and output electrodes Tx Rx varies as the touch panel or the display device including the touch panel bends, the touch panel according to at least one embodiment detects the degree and position of the bending by sensing the capacitance variation due to such a variation in distance between the two electrodes.

While the above embodiments have been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A touch panel, comprising:
a flexible substrate; and
a plurality of touch sensors formed over the flexible substrate, wherein each of the touch sensors includes:
a first conductive pattern;
a second conductive pattern at least partially overlapping the first conductive pattern; and
an insulating layer interposed between and electrically insulating the first and second conductive patterns,
wherein the insulating layer is formed at least in part of an elastic material, and
wherein the distance between the first and second conductive patterns is configured to vary as the flexible substrate is bent.

2. The touch panel of claim 1, wherein the first conductive pattern includes a first sub-region and a second sub-region having a greater thickness than the first sub-region.

3. The touch panel of claim 1, wherein each of the touch sensors is flexible and wherein the first and second conductive patterns of each touch sensor have a capacitance therebetween that increases as the distance therebetween decreases.

4. The touch panel of claim 2, wherein a cross-section of each of the first conductive patterns has a step shape and wherein the first sub-region is formed on opposing sides of the second sub-region in each of the first conductive patterns.

5. The touch panel of claim 1, further comprising a passivation layer at least partially covering the touch sensors.

6. The touch panel of claim 1, wherein each of the first and second conductive patterns has a cross-sectional shape that is substantially symmetrical.

7. The touch panel of claim 1, wherein the first and second conductive patterns have cross-sectional shapes that are complementary.

8. The touch panel of claim 1, wherein the first and second conductive patterns are formed at least in part of silver nanowire.

9. The touch panel of claim 1, wherein the flexible substrate is formed at least in part of a polymer resin layer.

10. A method of manufacturing a touch panel, comprising:
forming a flexible conductor over a substrate;
patterning the flexible conductor so as to form a plurality of first conductive patterns;
forming an insulating layer over the first conductive patterns; and
forming a plurality of second conductive patterns over the insulating layer, wherein the insulating layer electrically insulates the first conductive patterns from the second conductive patterns,
wherein the first and second conductive patterns have cross-sectional shapes that are complementary,
wherein the insulating layer is formed at least in part of an elastic material, and
wherein the distance between the first and second conductive patterns is configured to vary as the substrate is bent.

11. The method of claim 10, wherein the forming of each of the first conductive patterns includes:
forming a first sub-region; and
forming a second sub-region having a greater thickness than the first sub-region.

12. The method of claim 10, wherein the touch sensor is flexible and wherein the first and second conductive patterns have a capacitance therebetween that increases as the distance therebetween decreases.

13. The method of claim 11, wherein a cross-section of each of the first conductive patterns has a step shape and wherein the first sub-region is formed on opposing sides of the second sub-region in each of the first conductive patterns.

14. The touch panel of claim 10, further comprising forming a passivation layer at least partially covering the touch sensors.

15. The touch panel of claim 10, wherein the first and second conductive patterns have cross-sectional shapes that are substantially symmetrical.

16. The touch panel of claim 10, wherein the first and second conductive patterns are formed at least in part of silver nanowire.

17. The touch panel of claim 10, wherein the substrate comprises a polymer resin layer.

18. A flexible display device, comprising:
a flexible display panel including a plurality of pixels; and
a touch panel formed over the display panel, wherein the touch panel comprises:
a flexible substrate;
a plurality of first conductive patterns formed over the flexible substrate;
a plurality of second conductive patterns at least partially overlapping the first conductive patterns; and
an insulating layer interposed between and electrically insulating the first and second conductive patterns,
wherein the insulating layer is formed at least in part of an elastic material.

19. The device of claim 18, wherein each of the first conductive patterns comprises a first sub-region and a second sub-region having a thickness that is greater than that of the first sub-region.

20. The device of claim 18, further comprising a controller configured to:
measure a change in capacitance between the first and second conductive patterns; and
determine that the change in capacitance is due to bending of the touch panel when the change in capacitance is within a predetermined range.
